(19) United States
(12) Patent Application Publication
(10) Pub. No.: US 2026/0206153 A1
(43) Pub. Date: Jul. 16, 2026

(54) CASING HINGE AND DISPLAY

(71) Applicant: ViewSonic International Corporation, New Taipei City (TW)

(72) Inventors: Jia-Shin Tsai, New Taipei City (TW); Shun-Chang Chen, New Taipei City (TW); Chung-Hsien Shen, New Taipei City (TW)

(73) Assignee: ViewSonic International Corporation, New Taipei City (TW)

(21) Appl. No.: 19/284,719

(22) Filed: Jul. 30, 2025

(30) Foreign Application Priority Data
Jan. 15, 2025 (TW) 114101585

(51) Int. Cl. H05K 5/02; F16C 11/04

(52) U.S. Cl. CPC H05K 5/0226; F16C 11/04

(57) ABSTRACT

A casing hinge includes two brackets and two links. Each link is connected to the two brackets, forming a linkage mechanism. The two brackets move on a reference plane through the two links so that two casing fixing surfaces of the two brackets relatively rotate. The two casing fixing surfaces are perpendicular to the reference plane. A display includes two casings, two display modules, and the above-mentioned casing hinge. The casing hinge connects the two casings. The two display modules are assembled to the two casings respectively.

### BACKGROUND OF THE INVENTION

### 1. FIELD OF THE INVENTION

The present invention relates to a display, and more particularly to a casing hinge used for a display.

### 2. DESCRIPTION OF THE PRIOR ART

Currently, some large-screen displays adopt a design structure of splicing multiple display modules to form a screen. These display modules can be folded for easy storage. Therein, adjacent display modules can be connected by hinges. The structure of the hinge itself and the connection structure between the hinge and the adjacent display modules will affect the screen splicing effect.

### SUMMARY OF THE INVENTION

In view of the issues in the prior art, an objective of the present invention is to provide a casing hinge, which uses a multi-linkage mechanism to provide a stable connection structure, and fixing surfaces of which are used for fixing two casings and are perpendicular to the movement plane of the multi-linkage mechanism. This configuration facilitates positioning the two casings connected by the casing hinge.

A casing hinge of an embodiment according to the invention includes a first bracket, a second bracket, a first link, and a second link. The first bracket has a first guiding slot and a first casing fixing surface. The first guiding slot is a multi-section guiding slot. The second bracket has a second guiding slot and a second casing fixing surface. The second guiding slot is a multi-section guiding slot. A first end portion of the first link is pivotally connected to the first bracket. A second end portion of the first link slides in the second guiding slot. A third end portion of the second link is pivotally connected to the second bracket. A fourth end portion of the second link slides in the first guiding slot. The first link and the second link are pivotally connected. Therein, the first bracket and the second bracket move on a reference plane through the first link and the second link to make the first casing fixing surface and the second casing fixing surface rotate relatively, and the first casing fixing surface and the second casing fixing surface are perpendicular to the reference plane. Thereby, the first bracket, the second bracket, the first link, and the second link form a linkage mechanism. The two casings can be fixed to the first casing fixing surface and the second casing fixing surface respectively, so that the two casings can be firmly pivotally connected and relatively rotated through the linkage mechanism.

Another objective of the present invention is to provide a display, which uses a casing hinge to connect two casings, which facilitates positioning two display modules assembled to the two casings, thereby easily realizing the coplanar splicing of the screens of the two display modules.

A display of an embodiment according to the invention includes a first casing, a second casing, a first display module, a second display module, and a casing hinge. The casing hinge includes a first bracket, a second bracket, a first link, and a second link. The first bracket has a first guiding slot and a first casing fixing surface. The first guiding slot is a multi-section guiding slot. The second bracket has a second guiding slot and a second casing fixing surface. The second guiding slot is a multi-section guiding slot. A first end portion of the first link is pivotally connected to the first bracket. A second end portion of the first link slides in the second guiding slot. A third end portion of the second link is pivotally connected to the second bracket. A fourth end portion of the second link slides in the first guiding slot. The first link and the second link are pivotally connected. The first casing is fixed on the first casing fixing surface. The second casing is fixed on the second casing fixing surface. The first display module is assembled to the first casing. The second display module is assembled to the second casing. Therein, the first bracket and the second bracket move on a reference plane through the first link and the second link to make the first casing fixing surface and the second casing fixing surface rotate relatively, and the first casing fixing surface and the second casing fixing surface are perpendicular to the reference plane. Thereby, the first casing (together with the first display module) and the second casing (together with the second display module) are firmly pivotally connected and relatively rotatable through a linkage mechanism formed by the first bracket, the second bracket, the first link, and the second link of the casing hinge, so that the first display module and the second display module can be easily spliced on the same plane when needed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a display according to an embodiment.

FIG. 2 is a partially-exploded view of the display in FIG. 1.

FIG. 3 is an enlarged view of a casing combination of the display in the circle A in FIG. 2.

FIG. 4 is a partially-exploded view of a casing hinge, a first casing, and a second casing in FIG. 3.

FIG. 5 is a schematic diagram illustrating the casing hinge in FIG. 3.

FIG. 6 is a schematic diagram illustrating the casing hinge in FIG. 5 from another viewpoint.

FIG. 7 is a top view of the casing hinge in FIG. 5.

FIG. 8 is an exploded view of the casing hinge in FIG. 5.

FIG. 9 is a side view of the casing hinge in FIG. 5 in an unfolded state.

FIG. 10 is a side view of the casing hinge in FIG. 5 in a folded state.

FIG. 11 is an exploded view of a first cam part and a second cam part of the casing hinge.

FIG. 12 is a schematic diagram illustrating a relative relationship between the first cam part and the second cam part in the unfolded state.

FIG. 13 is a schematic diagram illustrating a relative relationship between the first cam part and the second cam part in the folded state.

### DETAILED DESCRIPTION

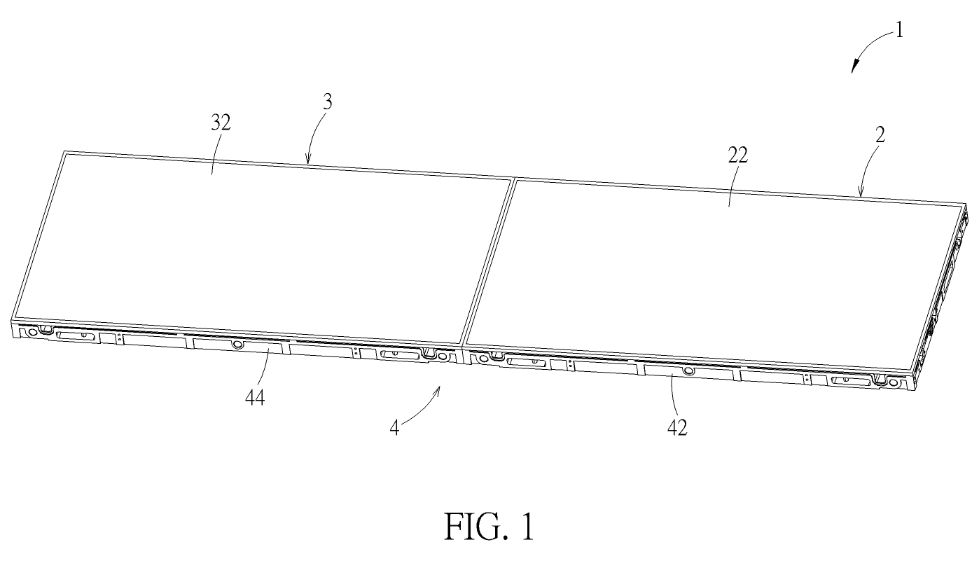

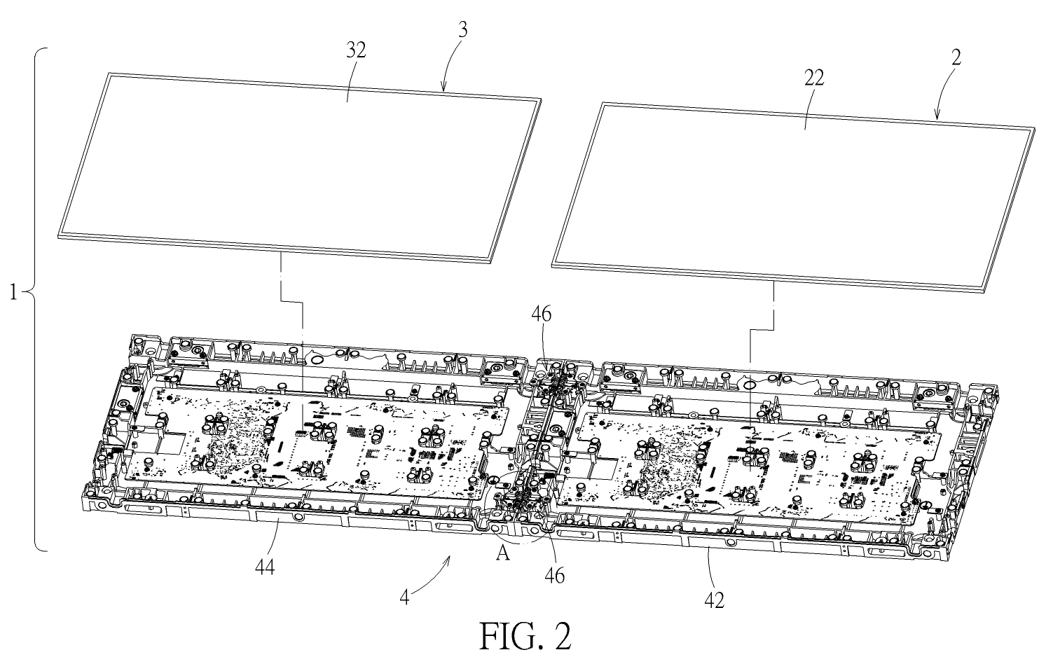

Please refer to FIG. 1 and FIG. 2. According to an embodiment, a display 1 includes a first display module 2 (represented by a simple block in the figures), a second display module 3 (represented by a simple block in the figures), and a casing combination 4. The casing combination 4 includes a first casing 42, a second casing 44, and two casing hinges 46. The first casing 42 and the second casing 44 are disposed adjacent to each other and connected through the casing hinges 46 (i.e., the first casing 42 and the second casing 44 are pivotally connected through the casing hinges 46). The first display module 2 is assembled to the first casing 42. The second display module 3 is assembled to the second casing 44. Thereby, the display 1 can be folded for easy storage; the display 1 can also be unfolded so that a first screen 22 of the first display module 2 and a second screen 32 of the second display module 3 are configured into a desired state, for example but not limited to, the first screen 22 and the second screen 32 are coplanar.

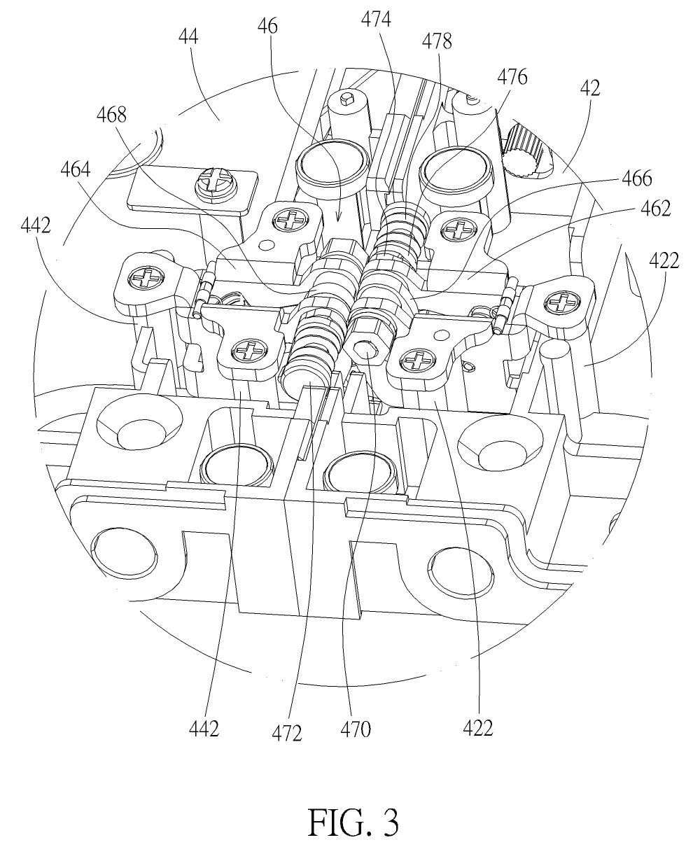

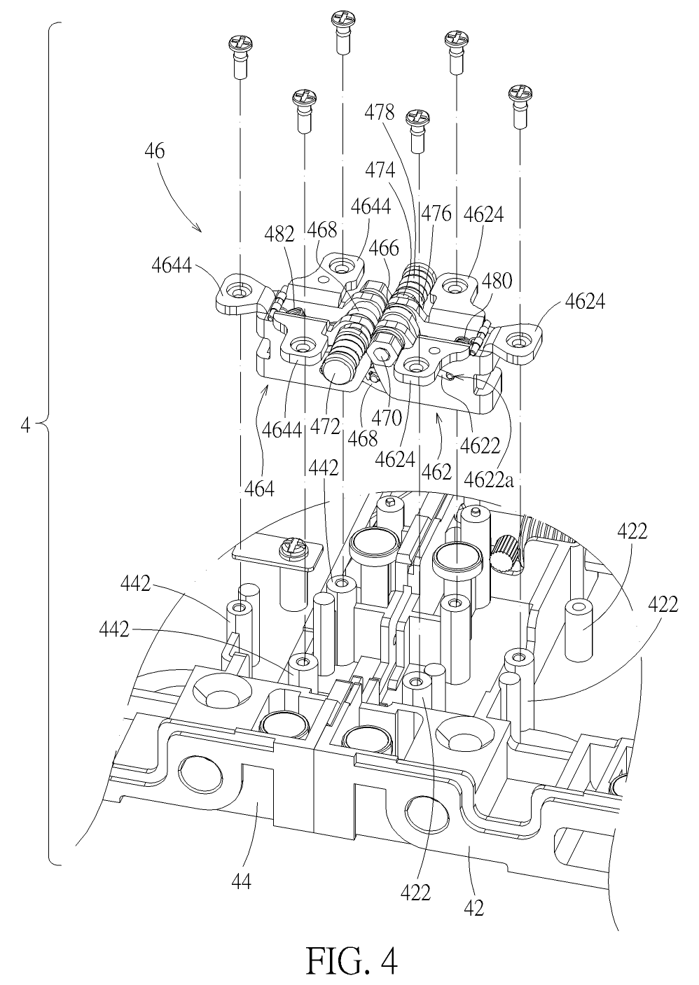

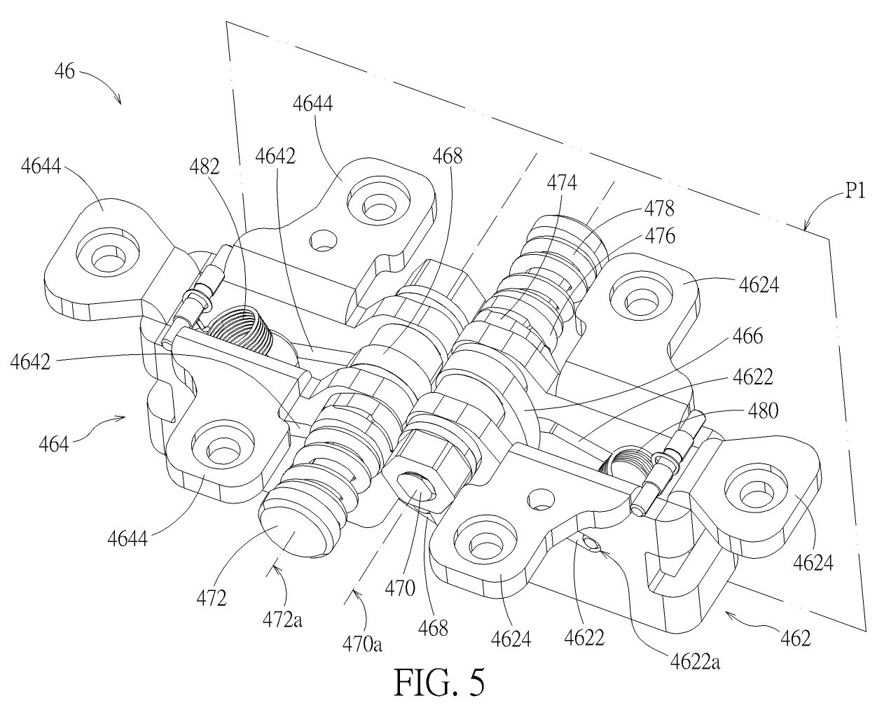

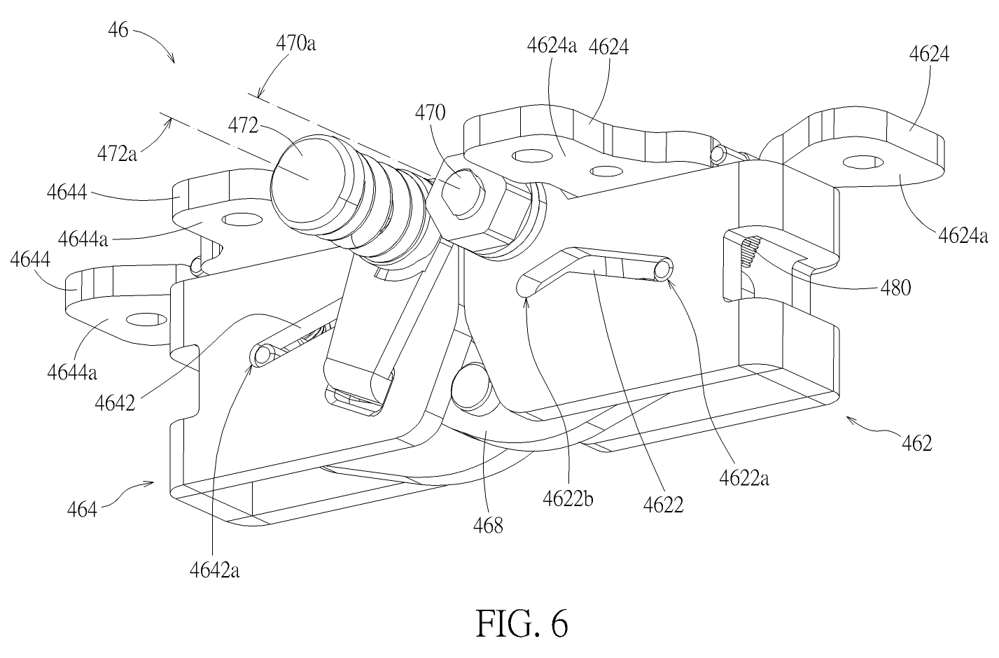

Please refer to FIG. 3 to FIG. 8. The casing hinge 46 includes a first bracket 462, a second bracket 464, a first link 466, and a second link 468. The first bracket 462 has side walls (three consecutive side walls) in a U-shaped configuration and two symmetrical first guiding slots 4622 are formed on two opposite side walls (of the three side walls). The second bracket 464 also has side walls (three consecutive side walls) in a U-shaped configuration and two symmetrical second guiding slots 4642 are formed on two opposite side walls (of the three side walls). The first link 466 has a first end portion 466a, a second end portion 466b, and a first middle portion 466c. The first middle portion 466c is located between the first end portion 466a and second end portion 466b. The first link 466 is entirely located between the two opposite side walls of the first bracket 462, and is also located between the two opposite side walls of the second bracket 464. The first link 466 is pivotally connected (relative to an axis 470a, which is shown by a chain line in FIG. 5 and FIG. 6) to (the two opposite side walls of) the first bracket 462 through the first end portion 466a (through a first shaft 470, e.g. passing through the first end portion 466a). The first link 466 slides in the second guiding slots 4642 with the second end portion 466b (through a shaft portion thereon) (that is, the two ends of the shaft portion are respectively slidably disposed in the two second guiding slots 4642). The second link 468 has a third end portion 468a, a fourth end portion 468b, and a second middle portion 468c. The second middle portion 468c is located between the third end portion 468a and the fourth end portion 468b. The second link 468 is also entirely located between the two opposite side walls of the first bracket 462 and between the two opposite side walls of the second bracket 464. The second link 468 is pivotally connected (relative to an axis 472a, which is shown by a chain line in FIG. 5 and FIG. 6) to (the two opposite side walls of) the second bracket 464 through the third end portion 468a (through a second shaft 472). The second link 468 slides in the first guiding slots 4622 with the fourth end portion 468b (through a shaft portion thereon) (that is, the two ends of the shaft portion are respectively slidably disposed in the two first guiding slots 4622). The first middle portion 466c of the first link 466 is pivotally connected to the second middle portion 468c of the second link 468 (through a shaft). Thereby, the first bracket 462, the second bracket 464, the first link 466, and the second link 468 form a linkage mechanism and all move parallel to a reference plane P1 (indicated by chain lines in FIG. 5) (in other words, the movement plane of each link is parallel to the reference plane P1, and the axes 470a, 472a are therefore perpendicular to the reference plane P1).

The casing hinge 46 is fixedly connected to the first casing 42 and the second casing 44 through the first bracket 462 and the second bracket 464, respectively. Therein, the first bracket 462 has three first fixing legs 4624 (which are bent and extended from the three side walls, respectively). Each first fixing leg 4624 has a first casing fixing surface 4624a. The second bracket 464 has three second fixing legs 4644 (which are bent and extended from the three side walls, respectively). Each second fixing leg 4644 has a second casing fixing surface 4644a. The first casing 42 is fixed to the three first casing fixing surfaces 4624a (through three posts 422) (for example, by screws), and the second casing 44 is fixed to the three second casing fixing surfaces 4644a (through three posts 442) (for example, by screws). The relative position between the first casing 42 and the second casing 44 is mainly determined by their positions relative to the casing hinge 46. In the embodiment, the first casing fixing surfaces 4624a and second casing fixing surfaces 4644a are all perpendicular to the reference plane P1. When the casing hinge 46 is in an unfolded state (as shown by FIG. 3), the first casing fixing surfaces 4624a and the second casing fixing surfaces 4644a are parallel. This structural configuration helps to maintain the relative positions of the first casing 42 and the second casing 44 in a vertical direction perpendicular to the first casing fixing surfaces 4624a (or the second casing fixing surfaces 4644a); that is, it helps to relatively position or align the first screen 22 and the second screen 32 in this direction (for example, to be coplanar). For example, even if the hole position tolerance of the post 422 or post 442 is large, it will not affect the above-mentioned relative position in the vertical direction. In addition, in the embodiment, the three first fixing legs 4624 are coplanar, and the three second fixing legs 4644 are also coplanar; however, it is not limited thereto in practice. For example, in coordination with the height difference configuration of the posts 422, the first fixing foots 4624 also have corresponding height position differences.

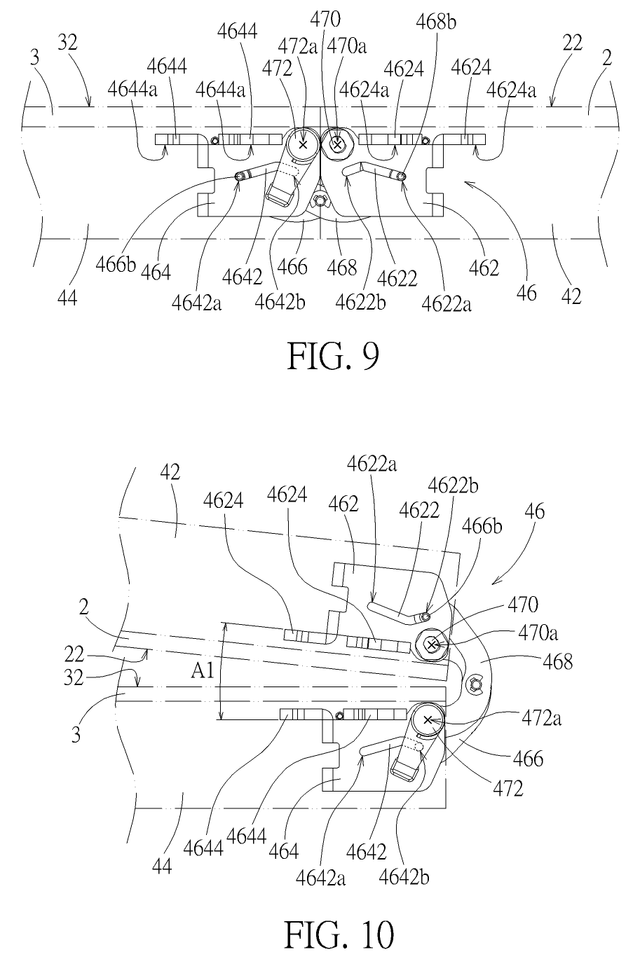

Please refer to FIG. 9 and FIG. 10, which are side views of the casing hinge 46 in the unfolded state and a folded state, respectively. Therein, the hidden outline of the second guiding slot 4642 of the second bracket 464 is shown in dotted lines; in addition, the outlines of the first display module 2, the second display module 3, the first casing 42, and the second casing 44 are roughly indicated by chain lines. In the linkage mechanism of the casing hinge 46, the first bracket 462 and the second bracket 464 are relatively rotated through the first link 466 and the second link 468 to switch the casing hinge 46 between the unfolded state (as shown by FIG. 9 or FIG. 5 ) and the folded state (as shown by FIG. 10 ). Therein, when the casing hinge 46 is in the unfolded state, the first bracket 462 and the second bracket 464 are adjacent to each other and laid flat side by side (at this time, it is not limited to leaving a fine gap between the first bracket 462 and the second bracket 464; for example, they are laid flat side by side and directly adjacent to each other), the first casing fixing surfaces 4624a of the first bracket 462 and the second casing fixing surfaces 4644a of the second bracket 464 are coplanar, the fourth end portion 468b (or its shaft portion) of the second link 468 is located at the first closed end 4622a (i.e., the end away from the second bracket 464) of the first guiding slot 4622, and the second end portion 466b (or its shaft portion) of the first link 466 is located at the third closed end 4642a (i.e., the end away from the first bracket 462) of the second guiding slot 4642. At this time, the first casing 42 and the second casing 44 are placed side by side and abut against each other, and the first screen 22 and the second screen 32 are coplanar (also referring to FIG. 1). At this time, the display 1 and the casing combination 4 are also in an unfolded state.

Moreover, when the casing hinge 46 is in the folded state, the first bracket 462 is arranged opposite to the second bracket 464, the fourth end portion 468b (or its shaft portion) of the second link 468 is located at the second closed end 4622b (i.e., the end close to the second bracket 464) of the first guiding slot 4622, and the second end portion 466b (or its shaft portion, whose hidden outline is shown in dotted lines in FIG. 10) of the first link 466 is located at the fourth closed end 4642b (i.e., the end close to the first bracket 462) of the second guiding slot 4642. At this time, the first casing 42 and the second casing 44 are also arranged opposite to each other, and the first screen 22 and the second screen 32 are also arranged opposite to each other. Furthermore, the display 1 and the casing combination 4 are also in a folded state at this time. In addition, in the embodiment, in the folded state, first casing fixing surface 4624a and the second casing fixing surface 4644a form an included angle A1, and the included angle A1 is designed to be an acute angle greater than 0 degrees. The acute angle design can ensure that there is a gap between the first display module 2 and the second display module 3 to facilitate the user to rotate (for example, by inserting a finger into the gap) the first casing 42 (together with the first display module 2) (relative to the second casing 44 and the second display module 3); however, it is not limited thereto in practice. For example, even if the included angle A1 is designed to be 0 degrees, the user can still rotate smoothly through a structural design (e.g., grooves are formed on the first casing 42 and the second casing 44 to facilitate the user to hook the grooves with their fingers; for another example, at this time, the first casing 42 (together with the first display module 2) and the second casing 44 (together with the second display module 3) are spaced apart from each other, leaving a gap for the user to insert a finger into). Furthermore, the included angle A1 can be an acute angle less than 10 degrees. In practice, the design of the included angle A1 may be determined according to the sizes of the first casing 42 and the second casing 44. In principle, the included angle A1 may be designed to allow the user to smoothly enter the gap.

In addition, in the embodiment, the third closed end 4642a of the second guiding slot 4642 blocks the second end portion 466b (or its shaft portion), the first closed end 4622a of the first guiding slot 4622 blocks the fourth end portion 468b (or its shaft portion), and the first casing 42 and the second casing 44 are closely adjacent to each other and placed side by side, which can all serve as positioning mechanisms for the unfolded state; in practice, one of them can be selected for implementation. In addition, in the embodiment, the first casing fixing surfaces 4624a and the second casing fixing surfaces 4644a are also parallel to the first screen 22 and the second screen 32, respectively, so the above-mentioned included angle A1 is also equivalent to an included angle formed by the first screen 22 and the second screen 32; on the other hand, when the casing hinge 46 is in the unfolded state, the included angle A1 is 180 degrees. Moreover, in the embodiment, the first guiding slot 4622 and the second guiding slot 4642 are multi-section guiding slots, for example, a zigzag slot formed by combining two sections of linear slots, but the number of the linear slots is not limited to two. Taking the first guiding slot 4622 as an example, the first guiding slot 4622 includes a first linear slot and a second linear slot, which extend toward each other from a first closed end 4622a and a second closed end 4622b, respectively. The first linear slot is farther away from the second bracket 464 than the second linear slot. The length of the first linear slot is greater than the length of the second linear slot. In the extending of the first linear slot and the second linear slot, the first linear slot and the second linear slot gradually approach the first casing fixing surfaces 4624a; that is, the first guiding slot 4622 is in an inverted V shape (as shown in FIG. 6). However, it is not limited thereto in practice. The guiding slot is not limited to a combination of linear slots, but may be a combination of curved slots or a combination of a linear slot and a curved slot.

Please refer to FIG. 5 to FIG. 8. In the embodiment, the first bracket 462 and the second bracket 464 have the same structure, and the first link 466 and the second link 468 also have the same structure. The following description takes the connection between the first bracket 462 and the first link 466 as an example. The connection between the second bracket 464 and the second link 468 can be directly referred to the connection between the first bracket 462 and the first link 466 and will not be described in addition. The casing hinge 46 also includes a first cam part 474, a second cam part 476, and an elastic part 478. The first shaft 470 rotatably passes through the first bracket 462. The first cam part 474 is fixed on the first bracket 462 and is sleeved on the first shaft 470 through a round hole, so that the first shaft 470 can rotate relative to the first cam part 474 (and the first bracket 462). The first end portion 466a (of the first link 466) and the second cam part 476 are both sleeved on the first shaft 470. The second cam part 476 is adjacent to the first cam part 474. The first end portion 466a and the second cam part 476 are both connected to the first shaft 470 to rotate synchronously with the first shaft 470; therein the above-mentioned connections are achieved through non-circular hole-shaft matching, but it is not limited thereto in practice (for example, achieved through a tight fit). The first cam part 474 has a first cam surface 4742. The second cam part 476 has a second cam surface 4762. The first cam surface 4742 and the second cam surface 4762 are disposed opposite to each other along the axis 470a of the first shaft 470 and abut against each other. The elastic part 478 is configured to apply force to the second cam part 476 to keep the second cam surface 4762 against the first cam surface 4742. Therein, the elastic part 478 is a metal coil spring and is compressed and sleeved on the first shaft 470 and pushes against the second cam part 476 (the two ends of the elastic part 478 are respectively against the head of the first shaft 470 (e.g., a bolt) and the second cam part 476); however, it is not limited thereto in practice. Furthermore, in practice, the required spring constant can be easily obtained by designing the wire diameter and spiral diameter of the coil spring. In General, compared with spring washers, coil springs allow larger elastic deformation and have better fatigue resistance.

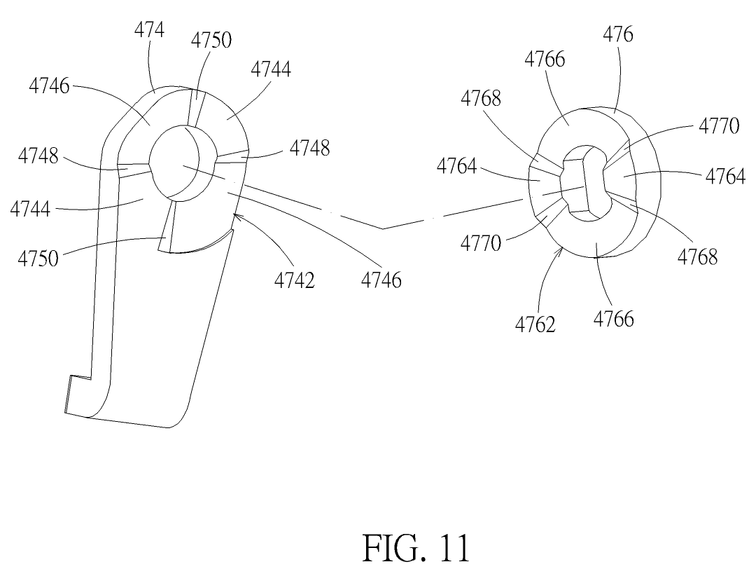

Please also refer to FIG. 11, which is an exploded view of the first cam part 474 and the second cam part 476. The first cam surface 4742 includes two first convex areas 4744 and two first concave areas 4746, which are arranged alternately. The first cam surface 4742 includes a first slope area 4748 and a second slope area 4750 on both sides of the first convex area 4744. The second cam surface 4762 includes two second convex areas 4764 and two second concave areas 4766, which are arranged alternately. The second cam surface 4762 includes a third slope area 4768 and a fourth slope area 4770 on both sides of the second convex area 4764. Thereby, due to the surface profile relationship between the first cam surface 4742 and the second cam surface 4762 and the force exerted by the elastic part 478 on the second cam part 476, when the first shaft 470 rotates (relative to the first bracket 462), the first shaft 470 drives the second cam surface 4762 to rotate around the axis 470a relative to the first cam surface 4742 and slide on the first cam surface 4742, so that the second cam part 476 moves away from or close to the first cam part 474 parallel to the axis 470a.

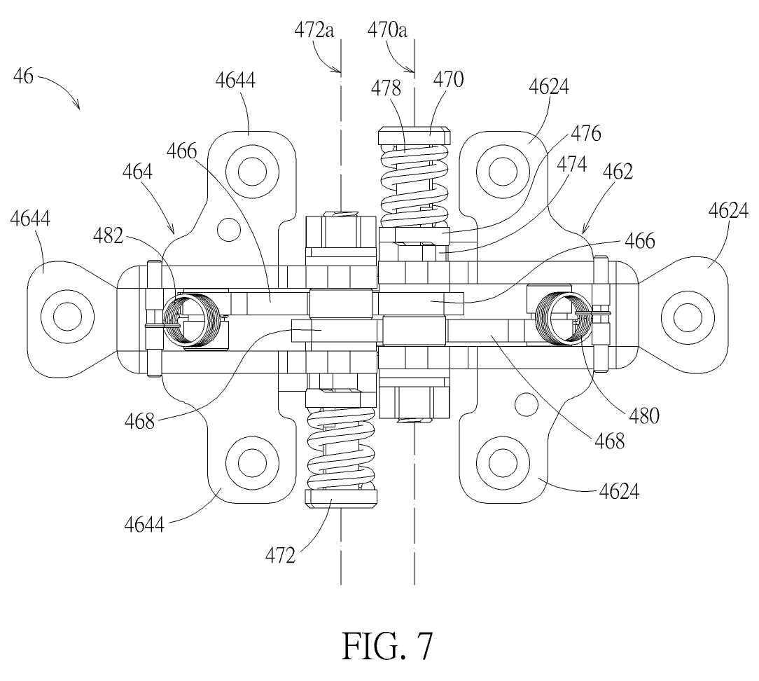

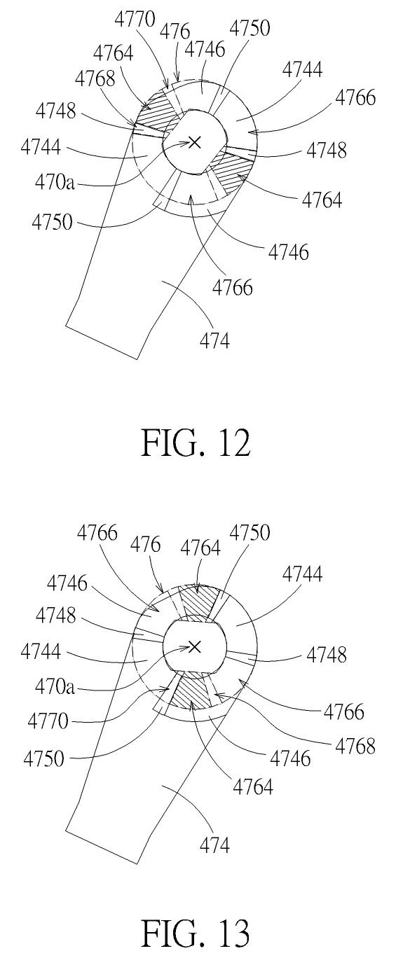

When the casing hinge 46 is in the unfolded state (as shown by FIG. 7) and the folded state, the two first convex areas 4744 are located in the two second concave areas 4766 and the two second convex areas 4764 are located in the two first concave areas 4746, such that the second cam part 476 is relatively close to the first cam part 474 along the axis 470a. Therein, when the casing hinge 46 is in the unfolded state, the third slope area 4768 abuts against the first slope area 4748 (as shown by FIG. 12, which is a front view of the first cam part 474 along the axis 470a; therein, the outline of the second cam part 476 (including its hidden outline) is shown in chain lines, the range of the second convex area 4764 is filled with oblique lines, and the axis 470a is indicated by a cross mark). Moreover, when the casing hinge 46 is in the folded state, the fourth slope area 4770 abuts against the second slope area 4750 (as shown by FIG. 13; the drawing description thereof is the same as that of FIG. 12 and will not be repeated in addition).

Furthermore, during the switching of the casing hinge 46 between the unfolded state and the folded state, for example, from the state shown by FIG. 12 to the state shown by FIG. 13, the second cam part 476 rotates counterclockwise relative to the axis 470a, so that the third slope area 4768 slides relative to the first slope area 4748 and the second cam part 476 moves away from the first cam part 474 along the axis 470a, then the second convex area 4764 slides on the first convex area 4744, and finally the fourth slope area 4770 slides relative to the second slope area 4750 and the second cam part 476 moves close to the first cam part 474 along the axis 470a; on the other hand, this switching process requires the second convex area 4764 to slide over the first convex area 4744. For another example, from the state shown by FIG. 13 to the state shown by FIG. 12, the second cam part 476 rotates clockwise relative to the axis 470a, and the second cam surface 4762 moves relative to the first cam surface 4742. The movement thereof is performed in the reverse direction of the above-mentioned movement (from the state shown in FIG. 12 to the state shown in FIG. 13), and will not be described in addition. Thereby, the switching of the casing hinge 46 between the unfolded state and the folded state requires overcoming the resistance of the second convex area 4764 sliding over the first convex area 4744, so the structural relationship between the first cam surface 4742 and the second cam surface 4762 has a positioning effect, which helps the casing hinge 46 to remain in the unfolded state (e.g., for use) and the folded state (e.g., for storage).

Furthermore, in the embodiment, the elastic part 478 keeps applying force to the second cam part 476, so when the first cam surface 4742 and the second cam surface 4762 slide relative to each other, friction force can be generated (which can be achieved by designing the mechanical properties of the elastic part 478 and/or the surface profiles of the first cam surface 4742 and the second cam surface 4762, and provides a damping feeling), which helps to maintain the relative position between the first casing 42 and the second casing 44 (for example, it is convenient for the user to configure the first screen 22 and the second screen 32 to be at an included angle of 120 degrees and use the display 1). In addition, in the embodiment, the protruding height of the first convex area 4744 relative to the first concave area 4746 is the same as the protruding height of the second convex area 4764 relative to the second concave area 4766. Therefore, when the first convex area 4744 abuts against the second concave area 4766, the second convex area 4764 also abuts against the first concave area 4746; however, it is not limited thereto in practice. For example, despite the above-mentioned protruding heights are different (for example, when the first convex area 4744 contacts the second concave area 4766, the second convex area 4764 does not contact the first concave area 4746), positioning functionality is still retained via the convex area; the structural details will not be described in addition.

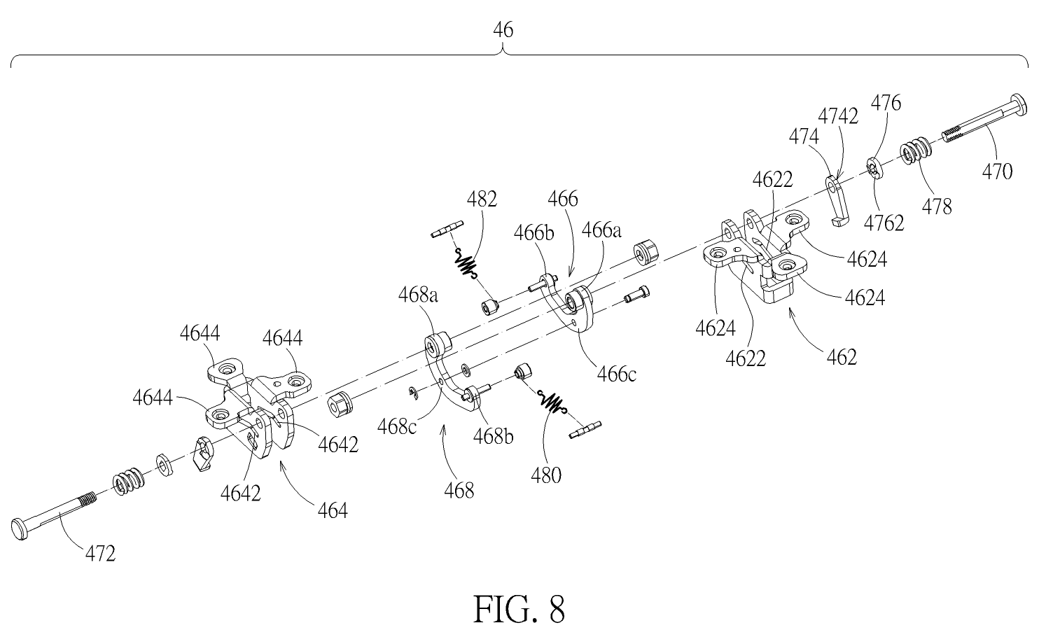

Please refer to FIG. 5, FIG. 7 and FIG. 8. In the embodiment, the casing hinge 46 also includes an elastic part 480. The elastic part 480 is located inside the first bracket 462 and connected to the first bracket 462 and the fourth end portion 468b of the second link 468 to drive the fourth end portion 468b to move toward the first closed end 4622a of the first guiding slot 4622; in other words, it helps the user to unfold the first casing 42 and the second casing 44 and helps the casing hinge 46 to remain in the unfolded state. The second bracket 464 also has the same structural configuration (the casing hinge 46 also includes another elastic part 482 inside of the second bracket 464) and has the same effect, which will not be described in addition.

In addition, the casing combination 4 in the embodiment is described by taking two adjacent casings pivotally connected as an example, but it is not limited thereto in practice. For example, in an embodiment, a side casing is pivotally connected to opposite sides of the main casing. The sizes of the two side casings (for installing the display modules) are smaller than that of the main casing, so that the two side casings can be folded toward the main casing at the same time without overlapping each other, which is convenient for storage. Moreover, the two side casings can be unfolded relative to the main casing to a desired configuration. The connection relationship of the side cases and the main case is the same as the related descriptions of the connection (through the casing hinges 46) and movement of the first casing 42 and the second casing 44, and will not be described in addition.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A casing hinge, comprising:
a first bracket, the first bracket having a first guiding slot and a first casing fixing surface, the first guiding slot being a multi-section guiding slot;
a second bracket, the second bracket having a second guiding slot and a second casing fixing surface, the second guiding slot being a multi-section guiding slot;
a first link, a first end portion of the first link being pivotally connected to the first bracket, a second end portion of the first link sliding in the second guiding slot; and
a second link, a third end portion of the second link being pivotally connected to the second bracket, a fourth end portion of the second link sliding in the first guiding slot, the first link and the second link being pivotally connected;
wherein the first bracket and the second bracket move on a reference plane through the first link and the second link to make the first casing fixing surface and the second casing fixing surface rotate relatively, and the first casing fixing surface and the second casing fixing surface are perpendicular to the reference plane.

2. The casing hinge according to claim 1, wherein the first guiding slot has a first linear slot and a second linear slot connected to each other, and a length of the first linear slot is greater than a length of the second linear slot.

3. The casing hinge according to claim 2, wherein the second linear slot is closer to the second bracket than the first linear slot.

4. The casing hinge according to claim 2, wherein the first linear slot extends from a first closed end of the first guiding slot toward the first casing fixing surface, and the second linear slot extends from a second closed end of the first guiding slot toward the first casing fixing surface.

5. The casing hinge according to claim 1, wherein when the casing hinge is in an unfolded state, the second end portion is located at a third closed end of the second guiding slot away from the first bracket, the fourth end portion is located at a first closed end of the first guiding slot away from the second bracket, and the first casing fixing surface and the second casing fixing surface are coplanar.

6. The casing hinge according to claim 1, wherein when the casing hinge is in a folded state, the fourth end portion is located at a second closed end of the first guiding slot close to the second bracket, the second end portion is located at a fourth closed end of the second guiding slot close to the first bracket, the first casing fixing surface and the second casing fixing surface form an included angle, and the included angle is an acute angle greater than 0 degrees.

7. The casing hinge according to claim 1, further comprising an elastic part, wherein the elastic part is connected to the first bracket and the fourth end portion.

8. The casing hinge according to claim 1, further comprising a shaft, a first cam part, and a second cam part, wherein the shaft passes through the first end portion, the first bracket, the first cam part, and the second cam part, the first cam part is fixed on the first bracket and has a first cam surface, the second cam part rotates synchronously with the shaft and has a second cam surface, and the first cam surface and the second cam surface abut against each other.

9. The casing hinge according to claim 8, further comprising an elastic part, wherein the elastic part is a coil spring, and the elastic part is compressed and sleeved on the shaft and pushes against the second cam part.

10. A display, comprising:
a casing hinge, comprising:
a first bracket, the first bracket having a first guiding slot and a first casing fixing surface, the first guiding slot being a multi-section guiding slot;
a second bracket, the second bracket having a second guiding slot and a second casing fixing surface, the second guiding slot being a multi-section guiding slot;
a first link, a first end portion of the first link being pivotally connected to the first bracket, a second end portion of the first link sliding in the second guiding slot; and
a second link, a third end portion of the second link being pivotally connected to the second bracket, a fourth end portion of the second link sliding in the first guiding slot, the first link and the second link being pivotally connected;
a first casing, the first casing being fixed on the first casing fixing surface;
a second casing, the second casing being fixed on the second casing fixing surface;
a first display module, the first display module being assembled to the first casing; and
a second display module, the second display module being assembled to the second casing;
wherein the first bracket and the second bracket move on a reference plane through the first link and the second link to make the first casing fixing surface and the second casing fixing surface rotate relatively, and the first casing fixing surface and the second casing fixing surface are perpendicular to the reference plane.

11. The display according to claim 10, wherein the first guiding slot has a first linear slot and a second linear slot connected to each other, and a length of the first linear slot is greater than a length of the second linear slot.

12. The display according to claim 11, wherein the second linear slot is closer to the second bracket than the first linear slot.

13. The display according to claim 11, wherein the first linear slot extends from a first closed end of the first guiding slot toward the first casing fixing surface, and the second linear slot extends from a second closed end of the first guiding slot toward the first casing fixing surface.

14. The display according to claim 10, wherein when the casing hinge is in an unfolded state, the second end portion is located at a third closed end of the second guiding slot away from the first bracket, the fourth end portion is located at a first closed end of the first guiding slot away from the second bracket, and the first casing fixing surface and the second casing fixing surface are coplanar.

15. The display according to claim 10, wherein when the casing hinge is in a folded state, the fourth end portion is located at a second closed end of the first guiding slot close to the second bracket, the second end portion is located at a fourth closed end of the second guiding slot close to the first bracket, the first casing fixing surface and the second casing fixing surface form an included angle, and the included angle is an acute angle greater than 0 degrees.

16. The display according to claim 10, wherein the casing hinge comprises an elastic part, and the elastic part is connected to the first bracket and the fourth end portion.

17. The display according to claim 10, wherein the casing hinge comprises a shaft, a first cam part, and a second cam part, the shaft passes through the first end portion, the first bracket, the first cam part, and the second cam part, the first cam part is fixed on the first bracket and has a first cam surface, the second cam part rotates synchronously with the shaft and has a second cam surface, and the first cam surface and the second cam surface abut against each other.

18. The display according to claim 17, wherein the casing hinge comprises an elastic part, the elastic part is a coil spring, and the elastic part is compressed and sleeved on the shaft and pushes against the second cam part.
